(19) United States
(12) Patent Application Publication
(10) Pub. No.: US 2010/0033929 A1
(43) Pub. Date: Feb. 11, 2010

(54) NOTEBOOK COMPUTER WITH A HEAT DISSIPATING DEVICE

(75) Inventor: XIAO-ZHU CHEN, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/208,690

(22) Filed: Sep. 11, 2008

(30) Foreign Application Priority Data
Aug. 11, 2008 (CN) 200810303649.5

(51) Int. Cl. H05K 7/20

(52) U.S. Cl. 361/695; 361/707

(57) ABSTRACT

A notebook computer includes a chassis and a heat dissipating device. The chassis has a receiving space for detachably receiving the heat dissipating device. For example, if the receiving space is configured to receive an installable device such as a CD drive or a battery compartment, then the heat dissipating device has a shape corresponding to the CD drive or a battery module. The heat dissipating device can be detachably received in the receiving space to further dissipate heat from the chassis when the installable device is not received in the receiving space.

### BACKGROUND

1. Field of the Invention

The present invention relates to a notebook computer and, more particularly, to a notebook computer with a heat dissipating device.

2. Description of Related Art

In recent years, the number of electronic components in a notebook computer has continually increased to achieve high performance while the volume of occupied space in the notebook computer has remained the same or been reduced. Thus, density of the components in the notebook computer has increased, which leads to heat dissipation problems.

Therefore, it is desired to provide a notebook computer and heat dissipating device to overcome the above-described shortcoming.

### BRIEF DESCRIPTION OF THE DRAWINGS

FIG. 1 is an exploded view of an embodiment of a notebook computer, the notebook computer including a chassis and a heat dissipating device.

FIG. 2 is an exploded view of an embodiment of the heat dissipating device of the notebook computer of FIG. 1.

FIG. 3 is an exploded view of the heat dissipating device of FIG. 2, but viewed from another aspect.

FIG. 4 is an assembled view of the heat dissipating device of FIG. 3.

### DETAILED DESCRIPTION

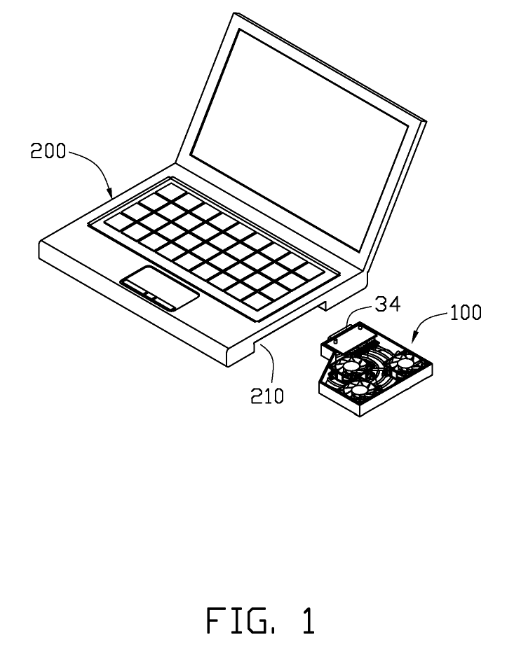

Referring to FIG. 1, an embodiment of a notebook computer includes a chassis 200 and a heat dissipating device 100. The chassis 200 includes a receiving space 210 for detachably receiving the heat dissipating device 100. The shape of the heat dissipating device 100 corresponds to the receiving space 210. For example, if the receiving space 210 is configured to receive an installable device such as a CD drive or a battery compartment, then the heat dissipating device 100 has a shape corresponding to the CD drive or a battery module.

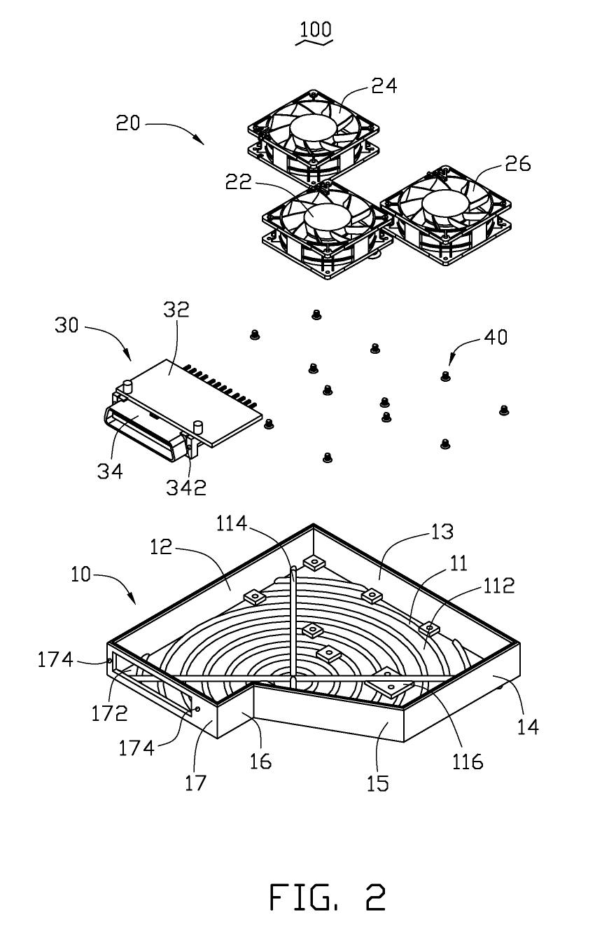

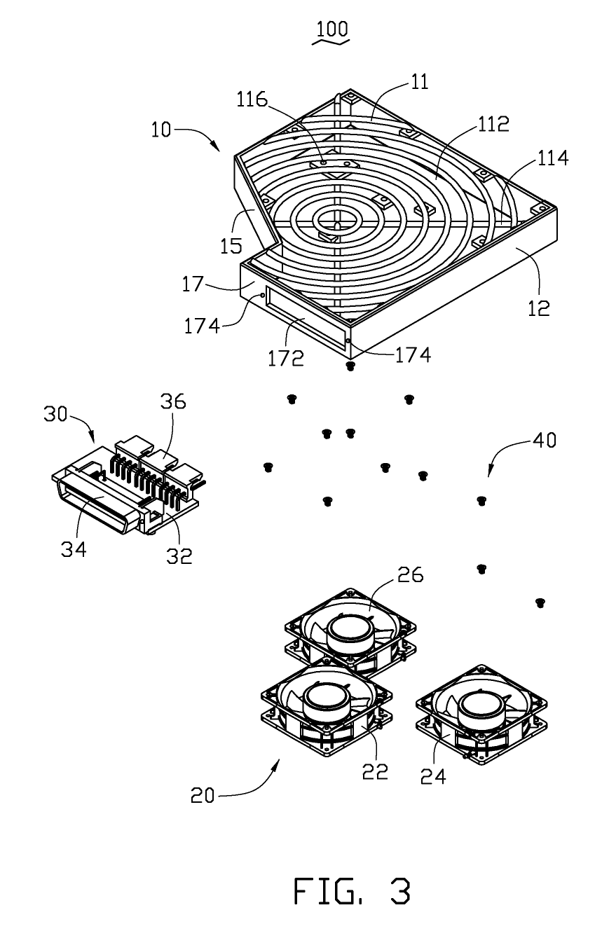

Referring also to FIGS. 2 and 3, the heat dissipating device 100 includes a bracket 10, a plurality of heat dissipaters 20, an adapter 30, and a plurality of screws 40. In the illustrated embodiment, the heat dissipaters 20 are fans 22, 24, 26.

The bracket 10 includes a base wall 11 with a polygonal shape, and a plurality of sidewalls 12 through 17 extending perpendicularly from edges of the base wall 11. The base wall 11 and the sidewalls 12 through 17 cooperatively define a receiving cavity to receiving the heat dissipaters 20. A plurality of ring-shaped through slots 112 is defined in the base wall 11 to communicate with outside to allow air to flow between inside and outside of the bracket 10. The base wall 11 includes an orthogonal supporting structure 114 positioned on the inside surface of the base wall 11 to reinforce the base wall 11, and a plurality of fixing blocks 116 extending from the base wall 11 inside the receiving cavity. A threaded hole is defined in each of the fixing blocks 116. An opening 172 and a pair of mounting holes 174 on opposite sides of the opening 172 corresponding to the two adapter holes 342 and adjacent to the opening 172 are defined in the sidewall 17.

Four through holes are defined in corners of the heat dissipaters 20.

The adapter 30 includes a main sheet 32, a power input connector 34 positioned on a first side of the main sheet 32, and power output connectors 36 positioned on a second side of the main sheet 32. The power input connector 34 is electrically connected to the power output connectors 36. The power input connector 34 is configured to connect to a power interface of the notebook computer and the power output connectors 36 are configured to connect to power terminals of the heat dissipaters 20. Two adapter holes 342 are defined in the main sheet 32 adjacent to the power input connector 34.

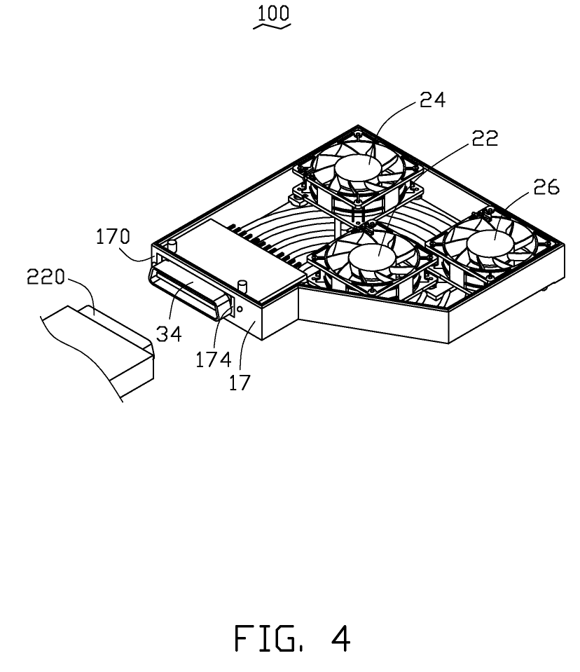

Referring also to FIG. 4, the power input connector 34 of the adapter 30 is received in the receiving cavity and protruding out through the opening 172 of the sidewall 17. The adapter 30 is attached to the sidewall 17, with two fasteners extended through the pair of mounting holes 174 and engaged in the adapter holes 342 of the adapter 30. In one embodiment, the heat dissipaters 20 are fixed on the fixing blocks 116 by inserting the screws 40 through the threaded holes of the fixing blocks 116 of the bracket 10 and screwed into the through holes of the heat dissipaters 20. In another embodiment, elastic latching members may be set on the base wall 11 to latch the heat dissipaters 20 thereon. The number of the heat dissipaters 20 can be added or reduced according to need.

In one embodiment, if a CD drive of a notebook computer is not received in the receiving space 210 of the chassis 200, the heat dissipating device 100 is inserted into the receiving space 210 of the chassis 200. The power input connector 34 of the adapter 30 is connected to a power interface 220 of the notebook computer to receive power for the heat dissipaters 20, thereby dissipating heat from the notebook computer. In other embodiments, the bracket 10 can be other shapes to correspond to another installable device receivable in the receiving space 210.

It is to be understood, however, that even though numerous characteristics and advantages of the embodiment have been set forth in the foregoing description, together with details of the structure and function of the embodiment, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A notebook computer comprising:
a chassis having a receiving space for receiving a installable device therein; and
a heat dissipating device having a shape corresponding to the installable device, detachably received in the receiving space to dissipate heat from the chassis when the installable device is not received in the receiving space.

2. The notebook computer as claimed in claim 1, wherein the heat dissipating device comprises a bracket, a plurality of heat dissipaters attached to the bracket, and an adapter attached to the bracket and configured to connect to a power source of the notebook computer to power the heat dissipaters.

3. The notebook computer as claimed in claim 2, wherein the bracket comprises a base wall, and a plurality of sidewalls extending perpendicularly from edges of the base wall, the base wall and the sidewalls cooperatively define a receiving cavity to receive the heat dissipaters.

4. The notebook computer as claimed in claim 3, wherein a plurality of ring-shaped through slots is defined in the base wall to communicate with an outside.

5. The notebook computer as claimed in claim 3, wherein an orthogonal supporting structure is positioned on an inside surface of the base wall to reinforce the base wall.

6. The notebook computer as claimed in claim 3, wherein a plurality of fixing blocks extends from the base wall inside the receiving cavity, a threaded hole is defined in each of the fixing blocks, a plurality of through holes are defined in the heat dissipaters; the heat dissipaters are attached to the base wall with a plurality of screws extending through the through holes of the heat dissipaters and engaging with the threaded holes.

7. The notebook computer as claimed in claim 3, wherein the adapter comprises a main sheet, a power input connector positioned on the main sheet, and a power output connectors positioned on the main sheet, the power input connector is electrically connected to the power output connectors; an opening is defined in one of the sidewalls to receive the power input connector therein.

8. The notebook computer as claimed in claim 7, wherein two adapter holes are defined in the main sheet adjacent to the power input connector; a pair of mounting holes are defined in the one of the sidewalls adjacent to the opening corresponding to the two adapter holes, two fasteners extend through the pair of mounting holes and the two adapter holes to attach the adapter to the bracket.

9. The notebook computer as claimed in claim 1, wherein the installable device is a CD drive.

10. A heat dissipating device configured for being detachably received in a receiving space of a notebook computer to dissipate heat from the notebook computer, the heat dissipating device comprising:
a bracket comprising a base wall and a plurality of sidewalls extending perpendicularly from edges of the base wall, the base wall and the sidewalls cooperatively defining a receiving cavity, wherein a plurality of through slots are defined in the base wall to communicate with an outside;
a plurality of heat dissipaters positioned on the base wall and received in the receiving cavity; and
an adapter configured to power the heat dissipaters, comprising:
a main sheet;
a power input connector positioned on the main sheet and configured to connect to a power terminal of the notebook computer; and
a power output connector positioned on the main sheet and connected to power terminals of the heat dissipaters, wherein the power input connector is electrically connected to the power output connector.

11. The heat dissipating device as claimed in claim 10, wherein an opening is defined in one of the sidewalls to receive the power input connector therein.

12. The heat dissipating device as claimed in claim 11, wherein two adapter holes are defined in the main sheet adjacent to the power input connector; a pair of mounting holes are defined in the one of the sidewalls adjacent to the opening corresponding to the two adapter holes; two fasteners extend through the pair of mounting holes and the two adapter holes to attach the adapter to the bracket.

13. The heat dissipating device as claimed in claim 10, wherein a plurality of fixing blocks extends from the base wall inside the receiving cavity, a threaded hole is defined in each of the fixing blocks, a plurality of through holes are defined in the heat dissipaters; the heat dissipaters are attached to the base wall with a plurality of screws extending through the through holes of the heat dissipaters and engaging with the threaded holes.

14. The heat dissipating device as claimed in claim 10, wherein an orthogonal supporting structure is positioned on an inside surface of the base wall to reinforce the base wall.

15. A bracket configured for fixing a plurality of heat dissipaters and being detachably received in a receiving space of notebook computer, the bracket comprising:
a base wall configured to fix the heat dissipaters, wherein a plurality of through slots are defined in the base wall to communicate with an outside;
a plurality of sidewalls extending perpendicularly from edges of the base wall, wherein a receiving cavity is cooperatively defined by the base wall and sidewalls to receive the heat dissipaters; and
an adapter configured to supply power to the heat dissipaters and attached to one of the sidewalls, comprising:
a main sheet;
a power input connector positioned on the main sheet and configured to connect to a power terminal of the notebook computer; and
a power output connector positioned on the main sheet and connected to power terminals of the heat dissipaters, wherein the power input connector is electrically connected to the power output connector.

16. The bracket as claimed in claim 15, wherein an opening is defined in one of the sidewalls to receive the power input connector therein.

17. The bracket as claimed in claim 16, wherein two adapter holes are defined in the main sheet adjacent to the power input connector; a pair of mounting holes are defined in the one of the sidewalls adjacent to the opening; two fasteners extend through the pair of mounting holes and the adapter holes of the main sheet to attach the adapter to the bracket.

18. The bracket as claimed in claim 15, wherein an orthogonal supporting structure is positioned on an inside surface of the base wall to reinforce the base wall.
